(19) United States
(12) Patent Application Publication
(10) Pub. No.: US 2015/0162371 A1
(43) Pub. Date: Jun. 11, 2015

(54) SEMICONDUCTOR DEVICE, MANUFACTURING METHOD FOR SEMICONDUCTOR DEVICE, AND ELECTRONIC DEVICE

(71) Applicant: SONY CORPORATION, Tokyo (JP)

(72) Inventors: Nobutoshi Fujii, Kanagawa (JP); Kenichi Aoyagi, Kanagawa (JP)

(21) Appl. No.: 14/407,198

(22) PCT Filed: Jun. 11, 2013
(86) PCT No.: PCT/JP2013/066090

§ 371 Date: Dec. 11, 2014

(30) Foreign Application Priority Data
Jun. 22, 2012 (JP) 2012-141284

(51) Int. Cl. H01L 27/146; H04N 5/225

(52) U.S. Cl. CPC H01L 27/14636; H01L 27/14683; H04N 5/2254

(57) ABSTRACT

The present disclosure includes a first substrate including a first wiring layer having a first connection electrode projecting by a predetermined quantity from a first interlayer insulation film and a second wiring layer having a second connection electrode projecting by a predetermined quantity from a second interlayer insulation film. On a bonded surface between the first and second substrates, the first and second connection electrodes are joined with each other, and at the same time, at least a part of the first interlayer insulation film and a part of the second interlayer insulation film which face to each other in a lamination direction are joined with each other.

### TECHNICAL FIELD

The present disclosure relates to a three-dimensional structure semiconductor device produced by bonding substrates together and a manufacturing method therefor. The present disclosure also relates to an electronic device having the semiconductor device.

### BACKGROUND ART

In a method for producing a three-dimensional structure large scale integration (LSI) by bonding devices (substrates) with each other, there is a method to directly join metal electrodes with each other which are exposed on a surface of the device. In the method to directly join the metal electrodes with each other, a method has been proposed in which the metal electrode and an interlayer insulation film (ILD) on the surface of the device are planarized so as to be the same surface and the metal electrodes and the interlayer insulation films are respectively joined with each other between the devices.

Generally, when the metal electrodes are joined by the above method, a method is employed in which a Cu electrode and the interlayer insulation film on the surface of the device are planarized and the devices are bonded with each other. However, actually, a dishing occurs at the time of chemical mechanical polishing (CMP) according to an area ratio between the Cu electrode and the interlayer insulation film on the surface of the device. Therefore, it is extremely difficult to obtain the flatness of joint surface to ensure an electrical connection by directly contacting the Cu electrodes with each other. There is a method to planarize the joint surface so that the surface of the Cu electrode and the surface of the interlayer insulation film become the same surface by selecting a preferable condition at the time of the CMP. However, it is difficult to stably and continuously arrange the CMP condition.

In recent years, a method has been proposed in which the Cu electrodes project from the interlayer insulation film and the projecting Cu electrodes are connected with each other (Patent Documents 1 and 2). However, in this method, although the Cu electrodes contact with each other, the interlayer insulation films do not contact with each other in the connection between the devices. Therefore, since the Cu electrode is exposed in the external space of the device, there is a possibility that Cu is diffused on the surface of the interlayer insulation film and the reliability is deteriorated.

Further, when the metal such as Cu is not coated, there is a possibility in many cases that Cu is corroded or causes metal contamination in a process for thinning the substrate, a chemical treatment, a plasma dry etching treatment, and the like performed after the connection. According to the above, it is not preferable that the joint surfaces other than the metal do not contact with each other in the joint between the metal electrodes with each other and between the interlayer insulation films with each other.

On the other hand, a method has been proposed in which an adhesive layer is formed on a bonding surface between the devices and the surfaces of the device except for the metal electrode are contacted with each other (Patent Document 3). However, in this case, there is a problem in heat resistance of an adhesive and non-proliferation ability of Cu. There is a possibility to have an influence on the reliability of the device.

### CITATION LIST

### Patent Document

Patent Document 1: JP 01-205465 A

Patent Document 2: JP 2006-191081 A

Patent Document 3: JP 2006-522461 W

### SUMMARY OF THE INVENTION

### Problems to be Solved by the Invention

In consideration of the above-mentioned point, a purpose of the present disclosure is to improve the heat resistance, diffusion resistance, and the reliability of a semiconductor device such as a solid imaging apparatus having a three-dimensional structure in which a plurality of substrates is laminated. Also, a manufacturing method for the semiconductor device and an electronic device having the semiconductor device are provided in the present disclosure.

### Solutions to Problems

A semiconductor device of the present disclosure includes a first substrate and a second substrate. The first substrate includes a first wiring layer having a first connection electrode which projects by a predetermined quantity from a first interlayer insulation film. Also, the second substrate includes a second wiring layer having a second connection electrode which projects by a predetermined quantity from a second interlayer insulation film. The second substrate is bonded and provided on the first substrate so as to join the second connection electrode with the first connection electrode. At this time, on a bonded surface between the first and second substrates, the first and second connection electrodes are joined, and at the same time, at least a part of the first interlayer insulation film and a part of the second interlayer insulation film which face to each other in a lamination direction are joined with each other.

In the semiconductor device of the present disclosure, on the bonded surface between the first and second substrates, the first and second connection electrodes are sealed by the first and second interlayer insulation films which are joined with each other.

A manufacturing method for the semiconductor device of the present disclosure includes a process for preparing the first substrate including the first wiring layer having the first connection electrode which projects by the predetermined quantity from the first interlayer insulation film. Also, the manufacturing method includes a process for preparing the second substrate including the second wiring layer having the second connection electrode which projects by the predetermined quantity from the second interlayer insulation film. Next, the manufacturing method includes a process for bonding the first connection electrode of the first substrate and the second connection electrode of the second substrate so that the first and second connection electrodes face to each other. On the bonded surface between the first and second substrates, the first and second substrates are bonded so that the first and second connection electrodes are joined with each other and at the same time at least a part of the first interlayer insulation film and a part of the second interlayer insulation film which face to each other in the lamination direction are joined with each other.

In the manufacturing method for the semiconductor device of the present disclosure, on the bonded surface between the first and second substrates bonded together, the first and second connection electrodes are sealed by the first and second interlayer insulation films which are joined with each other.

An electronic device of the present disclosure includes a solid imaging apparatus and a signal processing circuit. The solid imaging apparatus includes a sensor substrate and a circuit substrate. The sensor substrate includes a sensor-side semiconductor layer having a pixel region having a photoelectric converter provided therein and a sensor-side wiring layer. The sensor-side wiring layer is provided on a surface opposite to a light-receiving surface of the sensor-side semiconductor layer and has a wiring provided via a sensor-side interlayer insulation film and a sensor-side connection electrode which projects by the predetermined quantity from a surface of the sensor-side interlayer insulation film. Also, the circuit substrate includes a circuit-side semiconductor layer and a circuit-side wiring layer. The circuit-side wiring layer includes a wiring provided on a side of the sensor-side wiring layer of the sensor substrate and provided via a circuit-side interlayer insulation film and a circuit-side connection electrode which projects by the predetermined quantity from a surface of the circuit-side interlayer insulation film. The circuit substrate is bonded and provided on the sensor substrate. Also, on a bonded surface between the sensor substrate and the circuit substrate, the sensor-side connection electrode is joined with the circuit-side connection electrode, and at the same time, at least a part of the sensor-side interlayer insulation film and a part of the circuit-side interlayer insulation film which face to each other in the lamination direction are joined. The signal processing circuit performs processing on an output signal output from the solid imaging apparatus.

### Effects of the Invention

According to the present disclosure, a semiconductor device and an electronic device excellent in heat resistance and diffusion resistance and with high reliability can be obtained.

### BRIEF DESCRIPTION OF DRAWINGS

FIG. 1 is a cross-section diagram of a principal part of a solid imaging apparatus according to a first embodiment of the present disclosure.

FIGS. 2A to 2C are process diagrams of a manufacturing method for the solid imaging apparatus according to the first embodiment of the present disclosure.

FIG. 3 is a schematic diagram of a case where a position of a sensor-side connection electrode is deviated from a position of a circuit-side connection electrode by x in a plane direction.

FIG. 4 is a cross-section diagram of a principal part of a semiconductor device according to a second embodiment of the present disclosure.

FIGS. 5A to 5C are process diagrams of a manufacturing method for the semiconductor device according to the second embodiment of the present disclosure (part 1).

FIGS. 6D and 6E are process diagrams of the manufacturing method for the semiconductor device according to the second embodiment of the present disclosure (part 2).

FIGS. 7F and 7G are process diagrams of the manufacturing method for the semiconductor device according to the second embodiment of the present disclosure (part 3).

FIG. 8 is a schematic block diagram of an electronic device according to a third embodiment of the present disclosure.

### MODE FOR CARRYING OUT THE INVENTION

Non-patent Literature “Semiconductor Wafer Bonding”, Q. Y. Tong, U. Gosele; JOHN WILEY & SONS, Inc., 1999 discloses a technology regarding a Si substrate bonding. As a result of keen examination, the proposers of the technique of the present disclosure have found to apply the search result regarding an influence of a particle of the substrate on bonding to a technique for bonding electrodes together of the present disclosure.

An example of the semiconductor device, the manufacturing method therefor, and the electronic device according to the embodiments of the present disclosure will be described below with reference to the drawings.

The embodiments of present disclosure will be described in the following order. The technique of the present disclosure is not limited to the example below.

1. First embodiment: Solid imaging apparatus of two-layered structure

1-1. Cross-Sectional Structure

1-2. Manufacturing method

2. Second embodiment: Semiconductor device of three-layered structure

2-1. Cross-sectional structure

2-2. Manufacturing method

3. Third embodiment: Electronic device

### 1. First Embodiment

### Solid Imaging Apparatus of Two-Layered Structure

### 1-1 Cross-Sectional Structure

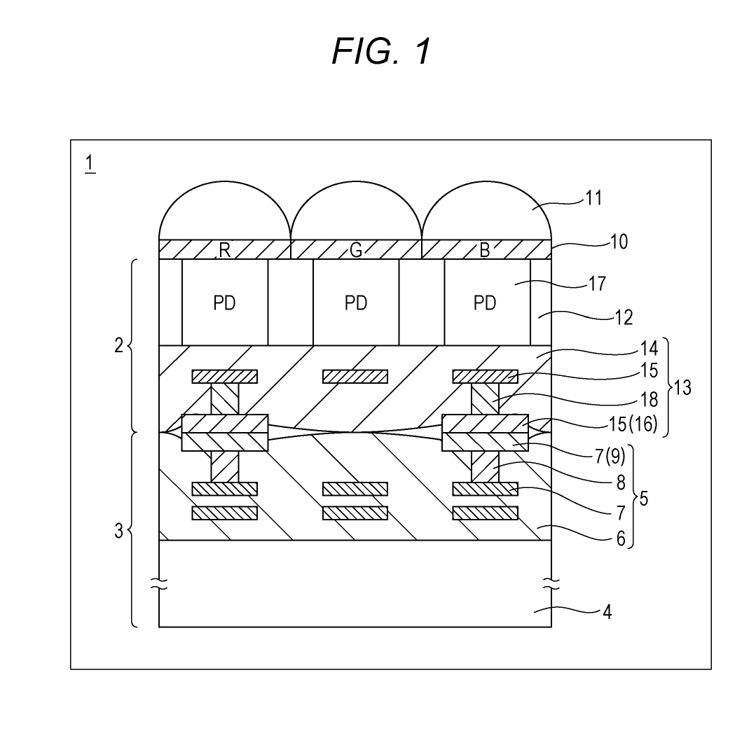

First, as an example of a semiconductor device according to a first embodiment of the present disclosure, a solid imaging apparatus will be described. FIG. 1 is a cross-section diagram of a principal part of a solid imaging apparatus 1 according to the first embodiment of the present disclosure. As illustrated in FIG. 1, the solid imaging apparatus 1 of the present embodiment is a solid imaging apparatus of a rear-surface irradiation type having a three-dimensional structure.

As illustrated in FIG. 1, the solid imaging apparatus 1 of the present embodiment includes a sensor substrate 2 and a circuit substrate 3 bonded on a surface opposite to a light-receiving surface of the sensor substrate 2. Also, the solid imaging apparatus 1 of the present embodiment includes a color filter 10 and an on-chip lens 11 provided on the light-receiving surface of the sensor substrate 2.

The sensor substrate 2 includes a sensor-side semiconductor layer 12 and a sensor-side wiring layer 13.

The sensor-side semiconductor layer 12 is a semiconductor substrate, for example, configured of single-crystal silicon. In a pixel region of the sensor-side semiconductor layer 12, a plurality of photoelectric converters 17 is arranged and formed in a two-dimensional array along the light-receiving surface (rear-surface in the present embodiment). Each photoelectric converter 17 has a lamination structure of an n-type diffusion layer and a p-type diffusion layer, for example. The photoelectric converter 17 is provided for each pixel, and a cross-sectional surface for three pixels is illustrated in FIG. 1.

Also, an impurity region including a read unit to read a signal charge accumulated in the photoelectric converter 17 and an impurity region including an element isolation unit are formed in the sensor-side semiconductor layer 12. The impurity regions are not shown in FIG. 1.

The sensor-side wiring layer 13 is provided on a surface opposite to the light-receiving surface of the sensor-side semiconductor layer 12 and includes a plurality of (two layers in FIG. 1) wirings 15 laminated via a sensor-side interlayer insulation film 14. The wiring 15 is formed of, for example, copper (Cu), and the sensor-side interlayer insulation film 14 is formed of, for example, SiO₂. Also, a read electrode, which is not shown, including the read unit to read the signal charge generated by the photoelectric converter 17 is provided on a side of the sensor-side semiconductor layer 12 in the sensor-side wiring layer 13. In the sensor-side wiring layer 13, the two wirings 15 adjacent to each other in a lamination direction and the wiring 15 and the read unit are connected with each other through a via 18 provided in the sensor-side interlayer insulation film 14 as necessary. A pixel circuit to read the signal charge of each pixel is configured by the plurality of wirings 15 provided in the sensor-side wiring layer 13 and the read electrode not shown.

Also, in the sensor-side wiring layer 13, the wiring 15 in the top layer (wiring 15 positioned on the most circuit substrate 3 side) is a sensor-side connection electrode 16 to ensure the electrical connection with the circuit substrate 3 and is provided so as to project from the surface of the sensor-side interlayer insulation film 14 and be exposed. In the present embodiment, a surface of the sensor-side connection electrode 16 and a surface of the sensor-side interlayer insulation film 14 become a bonded surface between the sensor substrate 2 and the circuit substrate 3.

The circuit substrate 3 includes a circuit-side semiconductor layer 4 and a circuit-side wiring layer 5.

The circuit-side semiconductor layer 4 is a semiconductor substrate, for example, configured of single-crystal silicon. In a surface layer for facing a side of the sensor substrate 2 of the circuit-side semiconductor layer 4, a source/drain region of a transistor which configures a part of the pixel circuit and an impurity layer such as the element isolation unit are provided. The source/drain region and the impurity layer are not shown.

The circuit-side wiring layer 5 is provided on a surface-side of the circuit-side semiconductor layer 4 and includes a wiring 7 having a plurality of layers (three layers in FIG. 1) laminated via the circuit-side interlayer insulation film 6. Also, a gate electrode of the transistor, which is not shown, for configuring a part of the pixel circuit is provided on a side of the circuit-side semiconductor layer 4 in the circuit-side wiring layer 5. The wiring 7 is formed of, for example, copper (Cu), and the circuit-side interlayer insulation film 6 is formed of, for example, SiO₂. Also, the two wirings 7 adjacent to each other in the lamination direction, and the wiring 7 and each transistor are connected with each other through a via 8 provided in the circuit-side interlayer insulation film 6 as necessary. A part of the pixel circuit and a drive circuit for driving the pixel circuit are configured by the transistor and the plurality of wirings 7 provided in the circuit-side wiring layer 5.

Also, in the circuit-side wiring layer 5, the wiring 7 in the top layer (wiring 7 positioned on the most sensor substrate 2 side) is a circuit-side connection electrode 9 to ensure the electrical connection with the sensor substrate 2 and is provided so as to project from the surface of the circuit-side interlayer insulation film 6 and be exposed. A surface of the circuit-side connection electrode 9 and a surface of the circuit-side interlayer insulation film 6 become the bonded surface between the sensor substrate 2 and the circuit substrate 3.

The color filters 10 are provided on the light-receiving surface of the sensor substrate 2 via a planarization film not shown and provided corresponding to the respective photoelectric converters 17. In the color filter 10, filter layers which selectively transmit light of, for example, red (R), green (G), and blue (B) are arranged for the respective pixels. Also, these filter layers are arranged for each pixel, for example, in a Bayer array.

The color filter 10 transmits the light with a desired wavelength, and the light having passed through the color filter 10 enters the photoelectric converter 17 in the sensor-side semiconductor layer 12. In the present embodiment, each pixel transmits the light of any one of R, G, and B. However, the color of the light is not limited to these. As a material for forming the color filter 10, an organic material which transmits the light of cyan, yellow, magenta, and the like may be used. The material can be variously selected according to a specification.

The on-chip lens 11 is formed above the color filter 10 and formed for each pixel. The incident light is concentrated in the on-chip lens 11, and the concentrated light efficiently enters the corresponding photoelectric converter 17 via the color filter 10. In the present embodiment, the on-chip lens 11 concentrates the incident light at the center position of the photoelectric converter 17.

In the present embodiment, the sensor substrate 2 and the circuit substrate 3 are bonded and laminated with each other and the sensor-side connection electrode 16 provided in the sensor-side wiring layer 13 and the circuit-side connection electrode 9 provided in the circuit-side wiring layer 5 are electrically connected with each other on the bonded surface. Accordingly, for example, the drive circuit for driving the pixel and the signal processing circuit for processing the signal obtained by the pixel can be provided in the circuit substrate 3. Therefore, a larger pixel area can be ensured in the sensor substrate 2.

Also, as will be described below, on the bonded surface between the sensor substrate 2 and the circuit substrate 3, the sensor-side connection electrode 16 is connected with the circuit-side connection electrode 9, and at the same time, the sensor-side interlayer insulation film 14 of an outermost surface of the sensor substrate 2 and the circuit-side interlayer insulation film 6 of an outermost surface of the circuit substrate 3 are joined with each other. Accordingly, surrounding areas of the sensor-side connection electrode 16 and the circuit-side connection electrode 9 are sealed by the interlayer insulation film. Therefore, the sensor-side connection electrode 16 and the circuit-side connection electrode 9 are not exposed in external space of the solid imaging apparatus 1.

### 1-2 Manufacturing Method

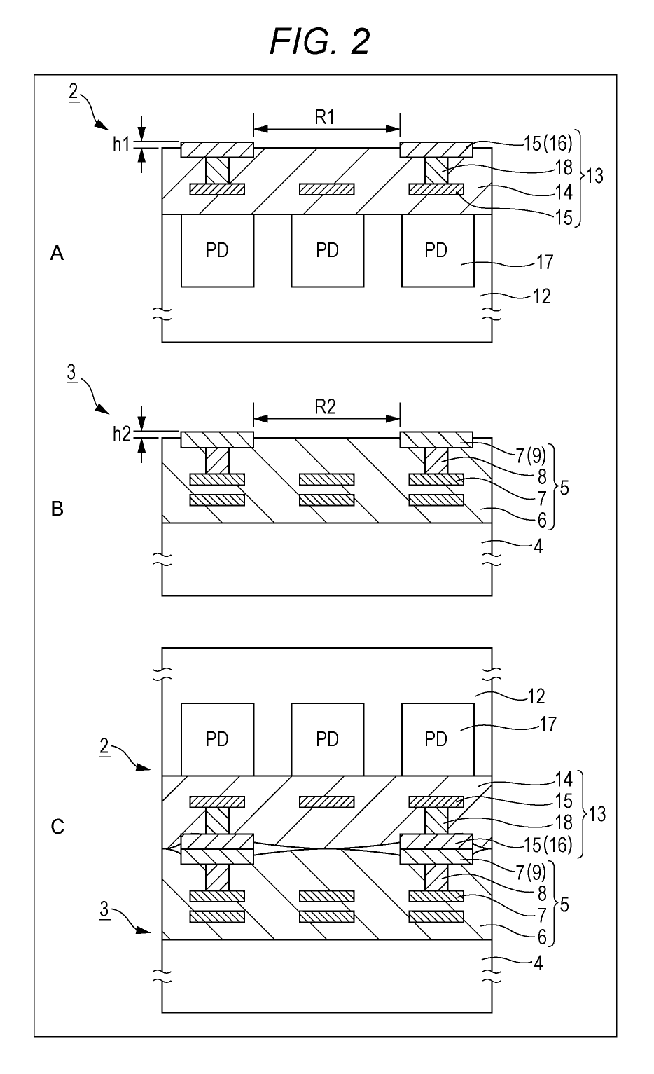

FIGS. 2A to 2C are process diagrams of a manufacturing method for the solid imaging apparatus 1 of the present embodiment. The manufacturing method for the solid imaging apparatus 1 of the present embodiment will be described with reference to FIGS. 2A to 2C.

First, as illustrated in FIG. 2A, the plurality of photoelectric converters 17 is formed in the pixel region in the sensor-side semiconductor layer 12, and at the same time, the desired impurity region which is not shown is formed. After that, the sensor substrate 2 is produced by forming the sensor-side wiring layer 13 on the surface of the sensor-side semiconductor layer 12. The photoelectric converter 17 and the desired impurity region not shown can be formed by ion implantation of a desired impurity on the surface of the sensor-side semiconductor layer 12.

Also, the sensor-side wiring layer 13 is formed by alternately repeating the formation of the sensor-side interlayer insulation film 14 and the formation of the wiring. At this time, a vertical hole is formed in the sensor-side interlayer insulation film 14 as necessary. Then, a via which connects the wiring 15 with the read unit and a via 18 which connects two wirings 15 adjacent to each other in the lamination direction are formed by embedding an electrically conductive material in the vertical hole. Also, the wiring 15 has been formed by using a so-called damascene method. In the damascene method, the electrically conductive material is embedded so as to coat a wiring groove and the sensor-side interlayer insulation film 14 and an electrically conductive material layer is polished by using the CMP method until the sensor-side interlayer insulation film 14 is exposed after the wiring groove has been formed in the sensor-side interlayer insulation film 14.

At this time, in the present embodiment, the sensor-side wiring layer 13 has been formed so that the wiring 15 which is the sensor-side connection electrode 16 in the top layer (the wiring 15 which is farthest from the sensor-side semiconductor layer 12) projects by a predetermined projection quantity h1 from the surface of the sensor-side interlayer insulation film 14 as illustrated in FIG. 2A. The projection quantity h1 of the sensor-side connection electrode 16 can be controlled by adjusting slurry when the electrically conductive material layer which is the sensor-side connection electrode 16 is polished by using the CMP method. The projection quantity h1 will be described below. Also, it is assumed that a distance between the sensor-side connection electrodes 16 adjacent to each other be R1.

Next, as illustrated in FIG. 2B, the circuit substrate 3 is produced by forming the circuit-side wiring layer 5 on the surface of the circuit-side semiconductor layer 4 after the impurity region which is not shown has been formed in the circuit-side semiconductor layer 4. The impurity region not shown can be formed by the ion implantation of the desired impurity on the surface of the circuit-side semiconductor layer 4.

Also, the circuit-side wiring layer 5 is formed by alternately repeating the formation of the circuit-side interlayer insulation film 6 and the formation of the wiring 7. At this time, a vertical hole is formed in the circuit-side interlayer insulation film 6 as necessary.

Then, a via which connects the wiring 7 with the transistor and a via 8 which connects two wirings 7 adjacent to each other in the lamination direction are formed by embedding the electrically conductive material in the vertical hole. Also, in the circuit substrate 3, the wiring 7 has been formed by using the damascene method. The circuit-side wiring layer 5 has been formed so that the wiring 7 which is the circuit-side connection electrode 9 in the top layer (the wiring 7 which is farthest from the circuit-side semiconductor layer 4) projects by a predetermined projection quantity h2 from the surface of the circuit-side interlayer insulation film 6. Also, it is assumed that a distance between the circuit-side connection electrodes 9 adjacent to each other be R2 (=R1).

The projection quantity h1 of the sensor-side connection electrode 16 and the projection quantity h2 of the circuit-side connection electrode 9 are controlled to satisfy the conditions indicated by following formulas (1) and (2).

$$\begin{matrix}[ Mathematical Formula 1 ] & \\ h 1 + h 2 > {[ \frac{2}{3} E {1}^{′} \frac{{t}_{w 1}^{3}}{γ} ]}^{- \frac{1}{4}} R {1}^{2} & ( 1 ) \\ h 1 + h 2 > {[ \frac{2}{3} E {2}^{′} \frac{{t}_{w 2}^{3}}{γ} ]}^{- \frac{1}{4}} R {2}^{2} & ( 2 )\end{matrix}$$

Here, E1′ is E1/(1−ν1²) (E1: Young's modulus of the sensor-side semiconductor layer 12, ν1: Poisson's ratio of the sensor-side semiconductor layer 12). E2′ is E2/(1−ν2²) (E2: Young's modulus of the circuit-side semiconductor layer 4, ν2: Poisson's ratio of the circuit-side semiconductor layer 4). Also, γ is a joint strength (surface energy) between the sensor-side interlayer insulation film 14 and the circuit-side interlayer insulation film 6. Also, R1 is the distance between the sensor-side connection electrodes 16 adjacent to each other, and R2 is the distance between the circuit-side connection electrodes 9 adjacent to each other. Also, t_{w1} is the thickness of the sensor-side semiconductor layer 12, and t_{w2} is the thickness of the circuit-side semiconductor layer 4.

The condition of the formula (1) is applied when R1>2t_{w1} and t_{w1}>>h1. The condition of the formula (2) is applied when R2>2t_{w2} and t_{w2}>>h2. Additionally, when the formulas (1) and (2) respectively satisfy 2t_{w1}=R1 and 2t_{w2}=R2 or when the formulas (1) and (2) respectively satisfy 2t_{w1}>R1 and 2t_{w2}>R2, the formulas (1) and (2) can be approximate to formulas (3) and (4) below.

$$\begin{matrix}[ Mathematical Formula 2 ] & \\ h 1 + h 2 = {5 [ \frac{γ {t}_{w 1}^{2}}{E {1}^{′}} ]}^{\frac{1}{2}} & ( 3 ) \\ h 1 + h 2 = {5 [ \frac{γ {t}_{w 2}^{2}}{E {2}^{′}} ]}^{\frac{1}{2}} & ( 4 )\end{matrix}$$

Furthermore, in a case where the sensor substrate 2 and the circuit substrate 3 are joined by receiving power from outside at the time of joint indicated in the process below, the projection quantities h1 and h2 are respectively set so as to satisfy formulas (5) and (6).

$$\begin{matrix}[ Mathematical Formula 3 ] & \\ h 1 + h 2 > {[ \frac{E {1}^{′}}{12 γ R 1} ]}^{- \frac{1}{2}} & ( 5 ) \\ h 1 + h 2 > {[ \frac{E {2}^{′}}{12 γ R 2} ]}^{- \frac{1}{2}} & ( 6 )\end{matrix}$$

In the present embodiment, it is assumed that each projection quantities h1 and h2 be 10 nm and each R1 and R2 be 50 μm as values for satisfying the above condition. In this case, the projection quantities h1 and h2 are set so as to satisfy the condition of Expression 2.

Next, as illustrated in FIG. 2C, the sensor substrate 2 is contacted with and bonded with the circuit substrate 3 after a surface on a side of the sensor-side connection electrode 16 of the sensor substrate 2 has been aligned with and faced to a surface on a side of the circuit-side connection electrode 9 of the circuit substrate 3 so that the connection electrodes thereof are faced to each other. The bonding process has been performed by depressing a center position of a wafer (for example, the sensor substrate 2) with a pin immediately after the polishing process according to the CMP method in the previous stage. In the present embodiment, it is assumed that a depression load be 12 N, and the wafer is depressed with a pin having a spherical front end.

In the present embodiment, the projection quantity h1 of the sensor-side connection electrode 16 in the sensor substrate 2 and the projection quantity h2 of the circuit-side connection electrode 9 in the circuit substrate 3 are set so as to satisfy the conditions indicated by the above-mentioned formulas (3) and (4). Therefore, since the both insulation films attract each other depending on the joint strength, the substrate itself is deformed (bent). Accordingly, on the bonded surface between the sensor substrate 2 and the circuit substrate 3, the sensor-side connection electrode 16 and the circuit-side connection electrode 9, which face to each other, are joined, and at the same time, the sensor-side interlayer insulation film 14 and the circuit-side interlayer insulation film 6, which face to each other, are joined with each other.

Next, although the process is not shown, the sensor-side semiconductor layer 12 of the sensor substrate 2 has been polished from a side of the rear-surface, and the sensor-side semiconductor layer 12 has been thinned. After that, the solid imaging apparatus 1 shown in FIG. 1 has been completed by forming the planarization film which is not shown, the color filter 10, and the on-chip lens 11 similarly to a normal manufacturing method for a solid imaging apparatus.

In the present embodiment, the sensor-side interlayer insulation film 14 and the circuit-side interlayer insulation film 6, which face to each other, are joined on the bonded surface between the sensor substrate 2 and the circuit substrate 3. Therefore, surrounding areas of the sensor-side connection electrode 16 and the circuit-side connection electrode 9 are respectively sealed by the sensor-side interlayer insulation film 14 and the circuit-side interlayer insulation film 6. Accordingly, on the bonded surface, the sensor-side connection electrode 16 and the circuit-side connection electrode 9 are not exposed to external environment of the solid imaging apparatus 1. Therefore, the sensor-side connection electrode 16 and the circuit-side connection electrode 9 are not exposed in chemical solution at the time of chemical treatment performed after bonding. Also, the two substrates can be bonded without using a material such as a resin with low heat resistance and low diffusion resistance on the bonded surface. Therefore, high-temperature processing can be performed without worrying about the heat resistance temperature after the bonding, and the reliability can be improved.

Also, in the present embodiment, the sensor-side connection electrode 16 and the circuit-side connection electrode 9 have projected by the predetermined projection quantity from the respective surfaces of the sensor-side interlayer insulation film 14 and the circuit-side interlayer insulation film 6 before the bonding. Therefore, in the present embodiment, since the acceptable range of a variation generated at the time of the planarization processing becomes bigger than that of the traditional bonding technique in which the surface of the interlayer insulation film and the surface of the connection electrode are planarized so as to be the same surface, mass producibility can be improved.

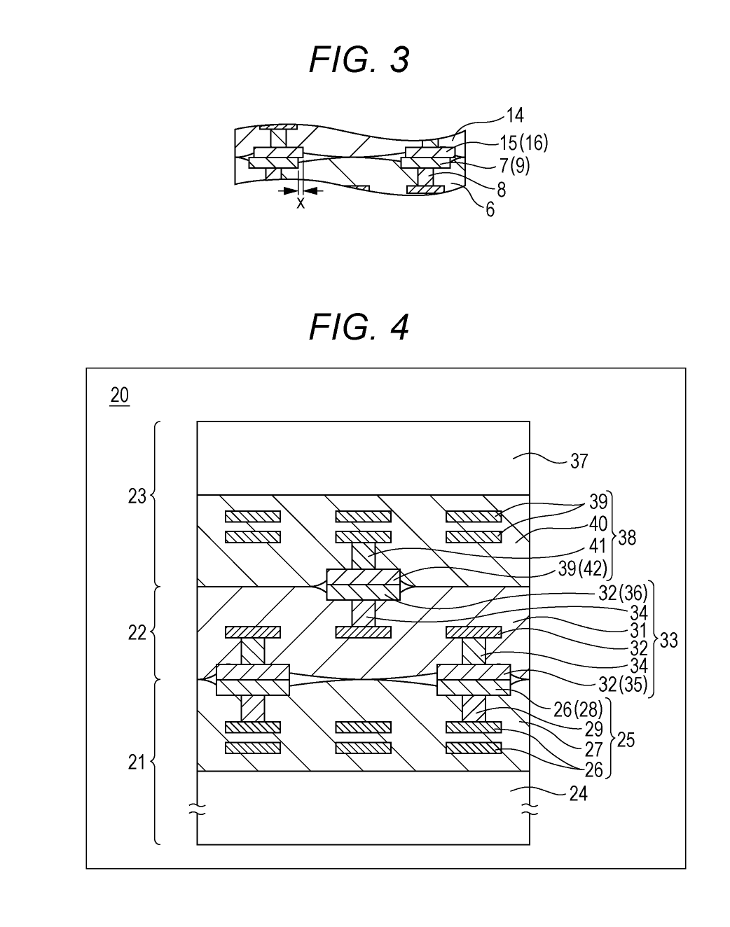

In the bonding process between the sensor substrate 2 and the circuit substrate 3, a position of the sensor-side connection electrode 16 may be deviated from a position of the circuit-side connection electrode 9. FIG. 3 is a schematic diagram of a case where the position of the sensor-side connection electrode 16 is deviated from the position of the circuit-side connection electrode 9 by x along the bonded surface. As illustrated in FIG. 3, even when the bonding position is deviated by x along the bonded surface between the sensor substrate 2 and the circuit substrate 3, the sensor-side interlayer insulation film 14 and the circuit-side interlayer insulation film 6 can be joined by setting the projection quantities h1 and h2 by displacing R1 with R1−x under the condition indicated by the formula 1.

As has been described above, the projection quantities h1 and h2 are set so as to satisfy a formula in which R1 is displaced with R1−x under the condition indicated by the formula 1 when the gap x is considered at the time of bonding the sensor substrate 2 with the circuit substrate 3. Accordingly, the CMP process can be performed with a margin, and the mass producibility can be improved.

### 2. Second Embodiment

### Semiconductor Device of Three-Layered Structure

### 2-1 Cross-Sectional Structure

Next, a semiconductor device according to a second embodiment of the present disclosure will be described. FIG. 4 is a cross-section diagram of a semiconductor device 20 of the present embodiment. A structure of the semiconductor device 20 of the present embodiment is a three-layered structure in which three layers of semiconductor substrates are laminated.

As illustrated in FIG. 4, the semiconductor device 20 of the present embodiment includes a first substrate 21, a second substrate 22, and a third substrate 23. The semiconductor device 20 also includes a lamination structure having the first substrate 21, the second substrate 22, and the third substrate 23 laminated in this order.

The first substrate 21 includes a first semiconductor layer 24 and a first wiring layer 25. The first semiconductor layer 24 is a semiconductor substrate, for example, configured of single-crystal silicon. In a surface layer on a side of the second substrate 22 in the first semiconductor layer 24, a source/drain region of a transistor which configures a predetermined circuit and an impurity layer such as an element isolation unit are provided as necessary. The source/drain region and the impurity layer are not shown.

The first wiring layer 25 is provided on a surface of the first semiconductor layer 24 and includes a plurality of wirings 26 (three layers in FIG. 4) laminated via a first interlayer insulation film 27. Also, a gate electrode of the transistor, which is not shown, for configuring the predetermined circuit is provided on a side of the first semiconductor layer 24 in the first wiring layer 25 as necessary. The wiring 26 is formed of, for example, copper (Cu), and the first interlayer insulation film 27 is formed of, for example, SiO₂. Also, the two wirings 26 adjacent to each other in a lamination direction, and the wiring 26 and each transistor are connected with each other through a via 29 provided in the first interlayer insulation film 27 as necessary. A first circuit includes the transistor and the plurality of wirings 26 provided in the first wiring layer 25.

Also, in the first wiring layer 25, the wiring 26 in the top layer (the wiring 26 positioned on the most second substrate 22 side) is a first connection electrode 28 to ensure an electrical connection with the second substrate 22 and is provided so as to project from a surface of the first interlayer insulation film 27. In the present embodiment, a surface of the first connection electrode 28 and a surface of the first interlayer insulation film 27 become a bonded surface between the first substrate 21 and the second substrate 22.

The second substrate 22 includes a second wiring layer 33. The second wiring layer 33 includes a plurality of wirings 32 (three layers in FIG. 4) laminated via a second interlayer insulation film 31. The wiring 32 is formed of, for example, copper (Cu), and the second interlayer insulation film 31 is formed of, for example, SiO₂. Also, as necessary, the two wirings 32 adjacent to each other in the lamination direction are connected with each other through a via 34 provided in the second interlayer insulation film 31. A second circuit includes the wirings 32 provided in the second wiring layer 33.

Also, in the second wiring layer 33, the wiring 32 in the top layer (the wiring 32 positioned on the most first substrate 21 side) is a lower-side connection electrode 35 to ensure the electrical connection with the first substrate 21 and is provided so as to project from a under surface of the second interlayer insulation film 31. Also, in the second wiring layer 33, the wiring 32 in the top layer (the wiring 32 positioned on the most third substrate 23 side) is an upper-side connection electrode 36 to ensure the electrical connection with the third substrate 23 and is provided so as to project from the upper surface of the second interlayer insulation film 31. In the present embodiment, the surface of the lower-side connection electrode 35 and the lower surface of the second interlayer insulation film 31 become the bonded surface between the first substrate 21 and the second substrate 22. The surface of the upper-side connection electrode 36 and the upper surface of the second interlayer insulation film 31 become the bonded surface between the second substrate 22 and the third substrate 23.

The third substrate 23 includes a third semiconductor layer 37 and a third wiring layer 38. The third semiconductor layer 37 is a semiconductor substrate, for example, configured of single-crystal silicon. In a surface layer on a side of the second substrate 22 in the third semiconductor layer 37, a source/drain region of a transistor which configures a predetermined circuit and an impurity layer such as the element isolation unit are provided as necessary. The source/drain region and the impurity layer are not shown.

The third wiring layer 38 is provided on a surface of the third semiconductor layer 37 and includes a plurality of layers of wirings 39 (three layers in FIG. 4) laminated via a third interlayer insulation film 40. Also, as necessary, a gate electrode of a transistor, which is not shown, for configuring a predetermined circuit is provided on the surface of the side of the third semiconductor layer 37 of the third wiring layer 38. The wiring 39 is formed of, for example, copper (Cu), and the third interlayer insulation film is formed of, for example, SiO₂. Also, as necessary, the two wirings 39 adjacent to each other in the lamination direction, and the wiring 39 and each transistor are connected with each other through a via 41 provided in the third interlayer insulation film 40. A third circuit includes the transistor and the plurality of wirings 39 provided in the third wiring layer 38.

Also, in the third wiring layer 38, the wiring 39 in the top layer (the wiring 39 positioned on the most second substrate 22 side) is a third connection electrode 42 to ensure the electrical connection with the second substrate 22 and is provided so as to project from a surface of the third interlayer insulation film 40. In the present embodiment, a surface of the third connection electrode 42 and a surface of the third interlayer insulation film 40 become the bonded surface between the third substrate 23 and the second substrate 22.

### 2-2 Manufacturing Method

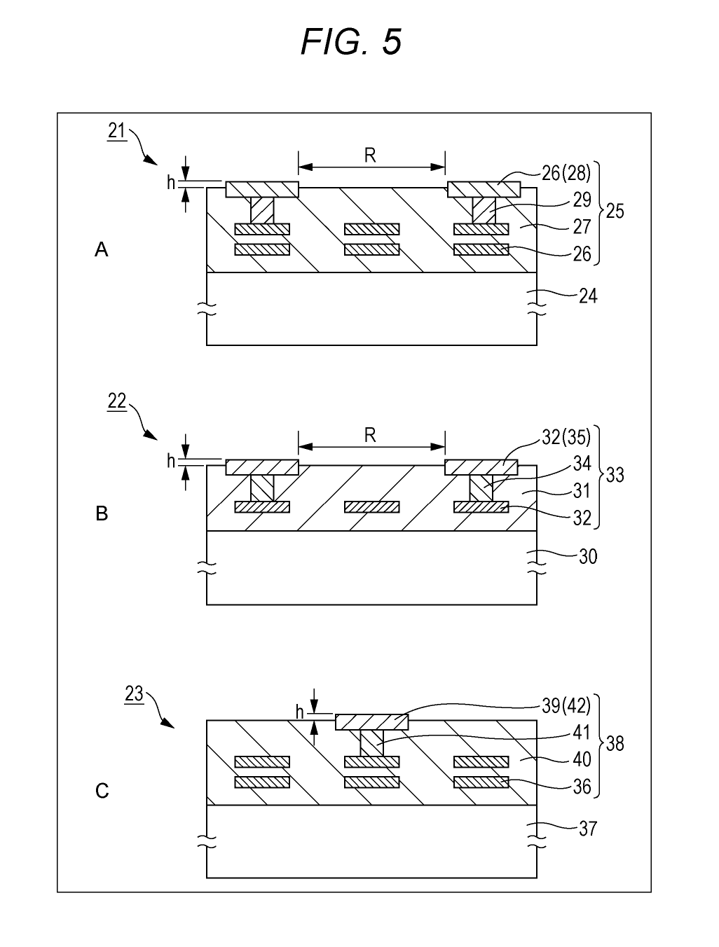

FIGS. 5A to 7G are process diagrams of a manufacturing method for the semiconductor device 20 of the present embodiment. The manufacturing method for the semiconductor device 20 of the present embodiment will be described with reference to FIGS. 5A to 7G.

First, as illustrated in FIG. 5A, the first substrate 21 is produced by forming the first wiring layer 25 on the surface of the first semiconductor layer 24 after an impurity region which is not shown has been formed in the first semiconductor layer 24. A desired impurity region not shown can be formed by ion implantation of desired impurity on the surface of the first semiconductor layer 24. Also, the first wiring layer 25 is formed by alternately repeating the formation of the first interlayer insulation film 27 and the formation of the wiring 26. At this time, a vertical hole is formed in the first interlayer insulation film 27 as necessary. Then, a via which connects the wiring 26 with the transistor and a via 29 which connects two wirings 26 adjacent to each other in the lamination direction are formed by embedding an electrically conductive material in the vertical hole. Also, the wiring 26 is formed by using the damascene method in the first substrate 21 similarly to the first embodiment. The first wiring layer 25 has been formed so that the wiring 26 in the top layer which is the first connection electrode 28 (the wiring 26 which is farthest from the first semiconductor layer 24) projects by the predetermined projection quantity h from the surface of the first interlayer insulation film 27. Also, it is assumed that a distance between the first connection electrodes 28 adjacent to each other be R.

Next, as illustrated in FIG. 5B, the second substrate 22 is produced by preparing a second semiconductor layer 30 and forming the second wiring layer 33 on the surface of the second semiconductor layer 30. Here, an upper-side connection electrode 36 in the second wiring layer 33 has not been formed yet. The second wiring layer 33 is formed by alternately repeating the formation of the second interlayer insulation film 31 and the formation of the wiring 32. At this time, a vertical hole is formed in the second interlayer insulation film 31 as necessary. Then, a via 34 which connects two wirings 32 adjacent to each other in the lamination direction is formed by embedding the electrically conductive material in the vertical hole. Also, in the second substrate 22, the wiring 32 has been formed by using the damascene method. The second wiring layer 33 has been formed so that the wiring 32 which is the lower-side connection electrode 35 in the bottom layer (the wiring 32 which is farthest from the second semiconductor layer 30) projects by a predetermined projection quantity h from the surface of the second interlayer insulation film 31. Also, it is assumed that a distance between the lower-side connection electrodes 35 adjacent to each other be R. The second semiconductor layer 30 is removed in the following process.

Next, as illustrated in FIG. 5C, the third substrate 23 is produced by forming the third wiring layer 38 on the surface of the third semiconductor layer 37 after an impurity region which is not shown has been formed in the third semiconductor layer 37. The impurity region not shown can be formed by the ion implantation of the desired impurity on the surface of the third semiconductor layer 37. Also, the third wiring layer 38 is formed by alternately repeating the formation of the third interlayer insulation film 40 and the formation of the wiring 39. At this time, a vertical hole is formed in the third interlayer insulation film 40 as necessary. Then, a via which connects the wiring 39 with the transistor and a via 41 which connects two wirings 39 adjacent to each other in the lamination direction are formed by embedding the electrically conductive material in the vertical hole. Also, in the third substrate 23, the wiring has been formed by using the damascene method. The third wiring layer 38 has been formed so that the wiring 39 which is the third connection electrode 42 in the top layer (the wiring 39 which is farthest from the third semiconductor layer 37) projects by the predetermined projection quantity h from the surface of the third interlayer insulation film 40. Also, it is assumed that a distance between the third connection electrodes 42 adjacent to each other, which are not shown, be R.

In the present embodiment, the projection quantities h of the first connection electrode 28, the lower-side connection electrode 35, and the third connection electrode 42 respectively in the first substrate 21, the second substrate 22, and the third substrate 23 can be set by using a conditional expression in which the projection quantity h1 in the formulas (1), (3), and (5) is replaced with the projection quantity h. When the projection quantity h of the first connection electrode 28 is obtained, it is assumed that E1 be the Young's modulus of the first semiconductor layer 24, ν1 be the Poisson's ratio of the first semiconductor layer 24, and γ be the joint strength (surface energy) between the first interlayer insulation film 27 and the second interlayer insulation film 31. Also, it is assumed that R1 be the distance R between the first connection electrodes 28 adjacent to each other and t_{w1} be the thickness of the first semiconductor layer 24.

Also, when the projection quantity h of the lower-side connection electrode 35 is obtained, it is assumed that E1 be the Young's modulus of the second semiconductor layer 30, ν1 be the Poisson's ratio of the second semiconductor layer 30, and γ be the joint strength (surface energy) between the second interlayer insulation film 31 and the first interlayer insulation film 27. Also, it is assumed that R1 be the distance R between the lower-side connection electrodes 35 adjacent to each other and t_{w1} be the thickness of the second semiconductor layer 30.

Also, when the projection quantity h of the third connection electrode 42 is obtained, it is assumed that E1 be the Young's modulus of the third semiconductor layer 37, ν1 be the Poisson's ratio of the third semiconductor layer 37, and γ be the joint strength (surface energy) between the third interlayer insulation film 40 and the second interlayer insulation film 31. Also, it is assumed that R1 be the distance R between the third connection electrodes 42 adjacent to each other and t_{w1} be the thickness of the third semiconductor layer 37.

In the present embodiment, as values for satisfying the above conditional expression, it is assumed that the projection quantities h of the first connection electrode 28, the lower-side connection electrode 35, and the third connection electrode 42 be 10 nm and the distance R between the respective connection electrodes be 50 nm.

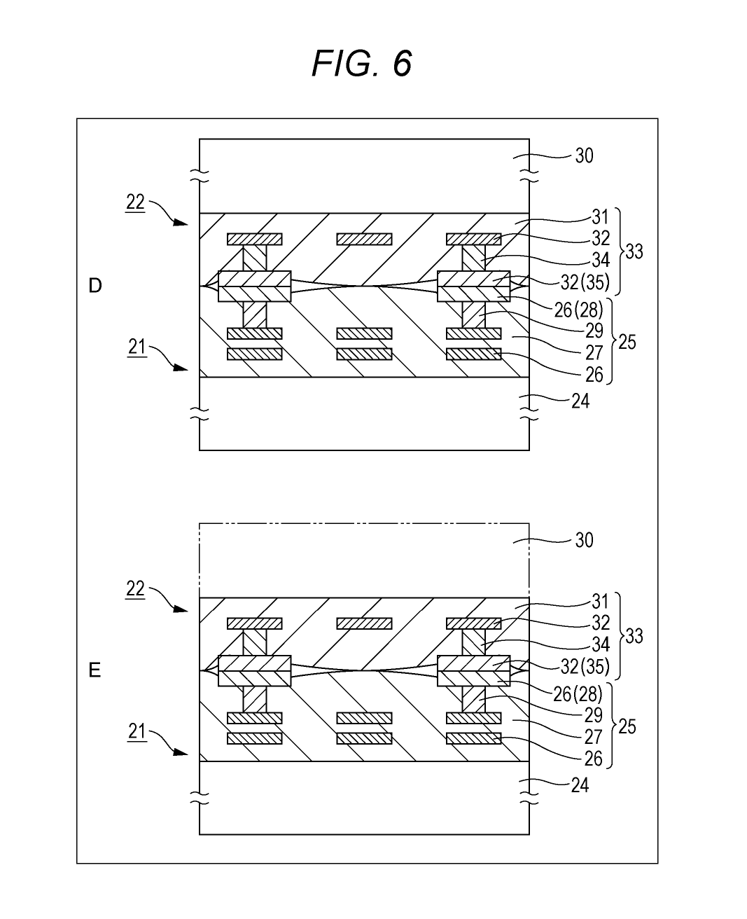

Next, as illustrated in FIG. 6D, the first substrate 21 is contacted with and bonded with the second substrate 22 after a surface on a side of the first connection electrode 28 of the first substrate 21 has been aligned with and faced to a surface on a side of the lower-side connection electrode 35 of the second substrate 22 so that the connection electrodes thereof are faced to each other. The bonding process has been performed by depressing a center position of a wafer (for example, the second substrate 22) with a pin immediately after the polishing process according to the CMP method in the previous stage. In the present embodiment, it is assumed that a depression load be 12 N, and the wafer is depressed with a pin having a spherical front end.

In the present embodiment, the projection quantity h of the first connection electrode 28 in the first substrate 21 and the projection quantity h of the lower-side connection electrode 35 in the second substrate 22 are set so as to satisfy the above conditional expression. Therefore, on the bonded surface between the first substrate 21 and the second substrate 22, the first connection electrode 28 and the lower-side connection electrode 35, which face to each other, are joined, and at the same time, the first interlayer insulation film 27 and the second interlayer insulation film 31, which face to each other, are joined.

Next, as illustrated in FIG. 6E, the second semiconductor layer 30 of the second substrate 22 is polished from the side of the rear-surface. After the second semiconductor layer 30 has been thinned until a film thickness of the second semiconductor layer 30 becomes 100 μm, the remaining second semiconductor layer 30 is separated from the second wiring layer 33 by the chemical solution. In the present embodiment, most regions of the first interlayer insulation film 27 and the second interlayer insulation film 31, which face to each other, are joined with each other on the bonded surface between the first substrate 21 and the second substrate 22. Therefore, in a separation process of the second semiconductor layer 30, the chemical solution does not penetrate into the bonded surface, and also, the first connection electrode 28 and the lower-side connection electrode 35 are not exposed in the chemical solution. As a result, the second semiconductor layer 30 can be removed without damaging the bonded surface between the first substrate 21 and the second substrate 22.

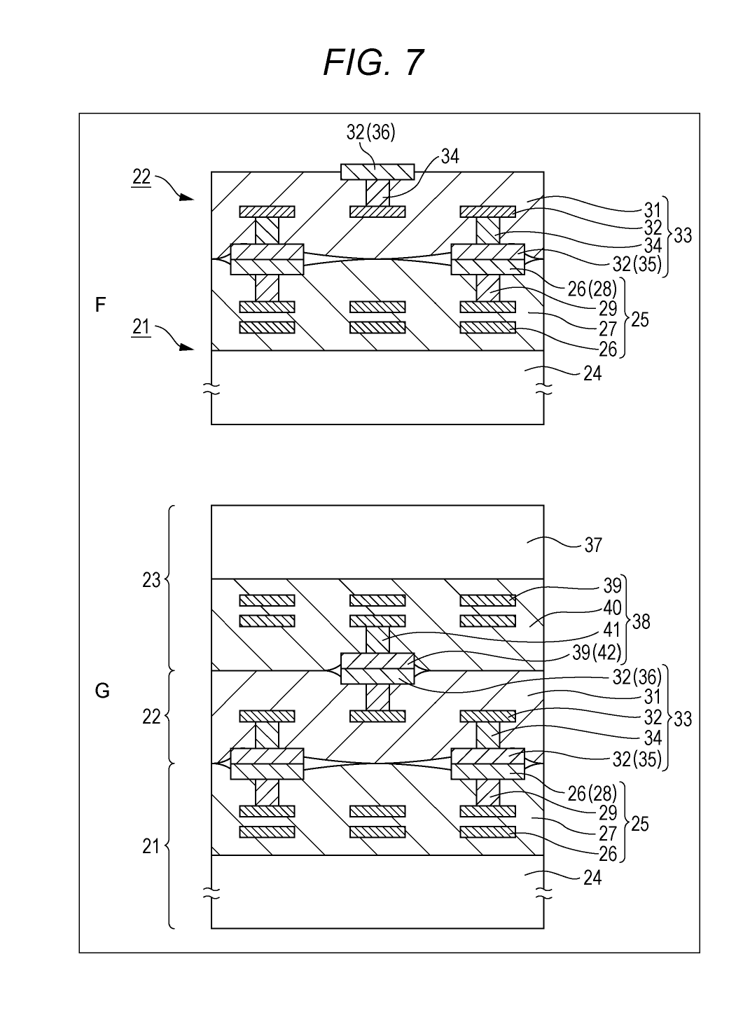

Next, as illustrated in FIG. 7F, the second circuit is completed by further forming the second interlayer insulation film 31, the wiring 32, and the via 34 on the second wiring layer 33 exposed by removing the second semiconductor layer 30. In the completed second wiring layer 33, the wiring 32 in the top layer (the wiring 32 provided on the opposite surface to the lower-side connection electrode 35) is the upper-side connection electrode 36 to ensure the electrical connection with the third substrate 23 and formed to project from the upper surface of the second interlayer insulation film 31. Also, in this case, the wiring 32 is formed by the damascene method and the amount of the polish is adjusted by using the CMP method so as to adjust the projection quantity h of the upper-side connection electrode 36 from the upper surface of the second interlayer insulation film 31. In the present embodiment, the projection quantity h of the upper-side connection electrode 36 is set to be the same as that of the lower-side connection electrode 35.

Next, as illustrated in FIG. 7G, the second substrate 22 is contacted with and bonded with the third substrate 23 after a surface of a side of the upper-side connection electrode 36 of the second substrate 22 has been aligned with and faced to a surface on a side of the third connection electrode 42 of the third substrate 23 so that the connection electrodes thereof are faced to each other. The bonding process has been performed by depressing the center position of the wafer (for example, the third substrate 23) with the pin immediately after the polishing process according to the CMP method at the time of forming the upper-side connection electrode 36. In the present embodiment, it is assumed that a depression load be 12 N, and the wafer is depressed with a pin having a spherical front end.

In the present embodiment, the projection quantity h of the upper-side connection electrode 36 in the second substrate 22 and the projection quantity h of the third connection electrode 42 in the third substrate 23 are set so as to satisfy the above conditional expression. Therefore, on the bonded surface between the second substrate 22 and the third substrate 23, the upper-side connection electrode 36 and the third connection electrode 42, which face to each other, are joined, and at the same time, the second interlayer insulation film 31 and the third interlayer insulation film 40, which face to each other, are joined with each other. After that, the third semiconductor layer 37 has been polished until it becomes a predetermined film thickness as necessary, and the semiconductor device 20 of the present embodiment illustrated in FIG. 4 has been completed.

In the semiconductor device 20 of the present embodiment, the second interlayer insulation film 31 and the third interlayer insulation film 40 are joined with each other on the bonded surface between the second substrate 22 and the third substrate 23. Therefore, also in a case where the third semiconductor layer 37 is polished after the bonding process in the FIG. 7G, the third semiconductor layer 37 can be polished without damaging the bonded surface between the second substrate 22 and the third substrate 23.

In the present embodiment, the effect similar to that of the first embodiment can be obtained. Also, the configuration of the semiconductor device 20 in this way can be applied to, for example, a semiconductor memory, and a semiconductor laser other than the solid imaging apparatus.

Also, in the example of the present embodiment, the first, second, and third circuits are electrically connected with one another on the bonded surface. However, the first, second, and third circuits are not limited to this example and may be respectively independent. In this case, each connection electrode on the bonded surface are used to connect the substrates.

### 3. Third Embodiment

### Electronic Device

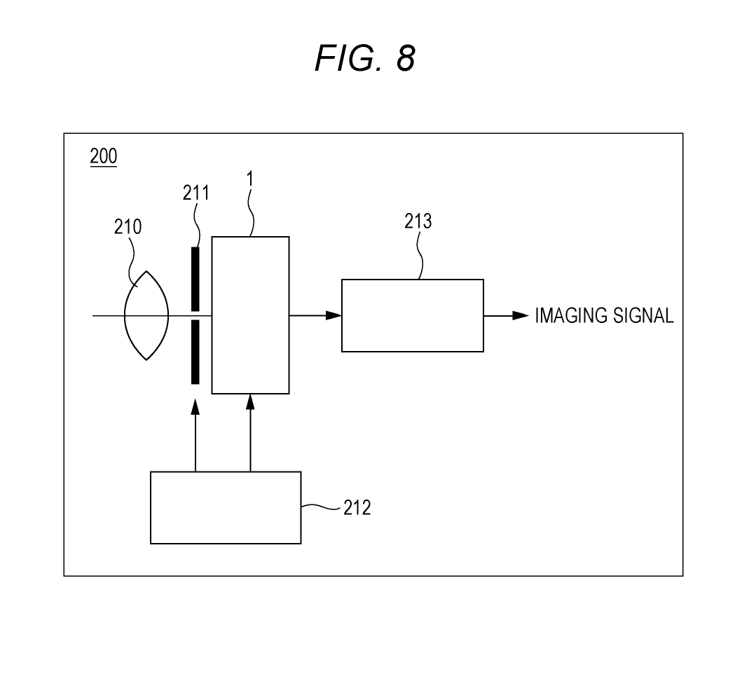

Next, an electronic device according to a third embodiment of the present disclosure will be described. FIG. 8 is a schematic block diagram of an electronic device 200 according to the third embodiment of the present disclosure.

The electronic device 200 according to the present embodiment includes a solid imaging apparatus 1, an optical lens 210, a shutter device 211, a drive circuit 212, and a signal processing circuit 213. In the present embodiment, am embodiment of a case will be described where the solid imaging apparatus 1 in the first embodiment of the present disclosure mentioned as the solid imaging apparatus 1 is used in an electronic device (digital still camera).

The optical lens 210 images imaging light (incident light) from a subject on an imaging surface of the solid imaging apparatus 1. Accordingly, a signal charge is accumulated in the solid imaging apparatus 1 for a certain period of time. The shutter device 211 controls a light irradiation period and a light blocking period relative to the solid imaging apparatus 1. The drive circuit 212 supplies a driving signal for controlling a signal transfer operation of the solid imaging apparatus 1 and a shutter operation of the shutter device 211. The solid imaging apparatus 1 transfers the signal according to the driving signal (timing signal) supplied from the drive circuit 212. The signal processing circuit 213 performs various signal processing relative to the signal output from the solid imaging apparatus 1. A video signal to which the signal processing has been performed is stored in a storage media such as a memory or output to a monitor.

In the electronic device 200 of the present embodiment, since the solid imaging apparatus 1 having a lamination structure is produced by a manufacturing method with high mass producibility and high reliability, the cost can be reduced.

Also, the present disclosure can have a configuration below.

(1)

A semiconductor device including:

a first substrate configured to include a first interlayer insulation film and a first wiring layer having a first connection electrode projecting by a predetermined quantity from the first interlayer insulation film; and

a second substrate configured to include a second interlayer insulation film and a second wiring layer having a second connection electrode projecting by a predetermined quantity from the second interlayer insulation film, wherein

the second connection electrode is bonded on the first substrate so as to join with the first connection electrode, and the second connection electrode is joined with the first connection electrode and at the same time at least a part of the first interlayer insulation film and a part of the second interlayer insulation film are joined with each other on the bonded surface.

(2)

The semiconductor device according to (1), wherein

the first substrate includes a first semiconductor layer, the first wiring layer is provided above the first semiconductor layer, the second substrate includes a second semiconductor layer, the second wiring layer is provided above the second semiconductor layer, and

a projection quantity h1 of the first connection electrode from the first interlayer insulation film and a projection quantity h2 of the second connection electrode from the second interlayer insulation film satisfy conditions of the following formulas (1) and (2) in a case where it is assumed that E1/(1−ν1²) be E1′ when it is assumed that E1 be Young's modulus of the first semiconductor layer and ν1 be Poisson's ratio of the first semiconductor layer, E2/(1−ν2²) be E2′ when it is assumed that E2 be the Young's modulus of the second semiconductor layer and ν2 be the Poisson's ratio of the second semiconductor layer, a joint strength between the first interlayer insulation film and the second interlayer insulation film be γ, a distance between the first connection electrodes adjacent to each other be R1, a thickness of the first semiconductor layer be t_{w1}, a distance between the second connection electrodes adjacent to each other be R2, and a thickness of the second semiconductor layer be t_{w2}.

$$\begin{matrix}[ Mathematical Formula 4 ] & \\ h 1 + h 2 = {5 [ \frac{γ {t}_{w 1}^{2}}{E {1}^{′}} ]}^{\frac{1}{2}} & ( 3 ) \\ h 1 + h 2 = {5 [ \frac{γ {t}_{w 2}^{2}}{E {2}^{′}} ]}^{\frac{1}{2}} & ( 4 )\end{matrix}$$

(3)

The semiconductor device according to (1), wherein

the first substrate includes a first semiconductor layer, the first wiring layer is provided above the first semiconductor layer, the second substrate includes a second semiconductor layer, the second wiring layer is provided above the second semiconductor layer, and

a projection quantity h1 of the first connection electrode from the first interlayer insulation film and a projection quantity h2 of the second connection electrode from the second interlayer insulation film satisfy conditions of the following formulas (3) and (4) in a case where it is assumed that E1/(1−ν1²) be E1′ when it is assumed that E1 be Young's modulus of the first semiconductor layer and ν1 be Poisson's ratio of the first semiconductor layer, E2/(1−ν2²) be E2′ when it is assumed that E2 be the Young's modulus of the second semiconductor layer and ν2 be the Poisson's ratio of the second semiconductor layer, a joint strength between the first interlayer insulation film and the second interlayer insulation film be γ, a thickness of the first semiconductor layer be t_{w1}, and a thickness of the second semiconductor layer be t_{w2}.

$$\begin{matrix}[ Mathematical Formula 5 ] & \\ h 1 + h 2 = {5 [ \frac{γ {t}_{w 1}^{2}}{E {1}^{′}} ]}^{\frac{1}{2}} & ( 3 ) \\ h 1 + h 2 = {5 [ \frac{γ {t}_{w 2}^{2}}{E {2}^{′}} ]}^{\frac{1}{2}} & ( 4 )\end{matrix}$$

(4)

The semiconductor device according to (1), wherein

the first substrate includes a first semiconductor layer, the first wiring layer is provided above the first semiconductor layer, the second substrate includes a second semiconductor layer, the second wiring layer is provided above the second semiconductor layer, and

a projection quantity h1 of the first connection electrode from the first interlayer insulation film and a projection quantity h2 of the second connection electrode from the second interlayer insulation film satisfy conditions of the following formulas (5) and (6) in a case where it is assumed that E1/(1−ν1²) be E1′ when it is assumed that E1 be Young's modulus of the first semiconductor layer and ν1 be Poisson's ratio of the first semiconductor layer, E2/(1−ν2²) be E2′ when it is assumed that E2 be the Young's modulus of the second semiconductor layer and ν2 be the Poisson's ratio of the second semiconductor layer, a joint strength between the first interlayer insulation film and the second interlayer insulation film be γ, a distance between the first connection electrodes adjacent to each other be R1, and a distance between the second connection electrodes adjacent to each other be R2.

$$\begin{matrix}[ Mathematical Formula 6 ] & \\ h 1 + h 2 > {[ \frac{E {1}^{′}}{12 γ R 1} ]}^{- \frac{1}{2}} & ( 5 ) \\ h 1 + h 2 > {[ \frac{E {2}^{′}}{12 γ R 2} ]}^{- \frac{1}{2}} & ( 6 )\end{matrix}$$

(5)

A manufacturing method for a semiconductor device, including:

a step of preparing a first substrate including a first wiring layer having a first connection electrode projecting by a predetermined quantity from a first interlayer insulation film;

a step of preparing a second substrate including a second wiring layer having a second connection electrode projecting by a predetermined quantity from a second interlayer insulation film; and

a step of bonding the first connection electrode of the first substrate with the second connection electrode of the second substrate while facing them to each other and bonding the first substrate with the second substrate so that the first connection electrode and the second connection electrode are joined and at the same time at least a part of the first interlayer insulation film and a part of the second interlayer insulation film, which face to each other in a lamination direction, are joined with each other on the bonded surface.

(6)

The manufacturing method for a semiconductor device according to (5), wherein

the first substrate includes a first semiconductor layer, the first wiring layer is provided above the first semiconductor layer, the second substrate includes a second semiconductor layer, the second wiring layer is provided above the second semiconductor layer, and

the first substrate and the second substrate are formed so that a projection quantity h1 of the first connection electrode from the first interlayer insulation film and a projection quantity h2 of the second connection electrode from the second interlayer insulation film satisfy conditions of the following formulas (1) and (2) in a case where it is assumed that E1/(1−ν1²) be E1′ when it is assumed that E1 be Young's modulus of the first semiconductor layer and ν1 be Poisson's ratio of the first semiconductor layer, E2/(1−ν2²) be E2′ when it is assumed that E2 be the Young's modulus of the second semiconductor layer and ν2 be the Poisson's ratio of the second semiconductor layer, a joint strength between the first interlayer insulation film and the second interlayer insulation film be γ, a distance between the first connection electrodes adjacent to each other be R1, a thickness of the first semiconductor layer be t_{w1}, a distance between the second connection electrodes adjacent to each other be R2, and a thickness of the second semiconductor layer be t_{w2}.

$$\begin{matrix}[ Mathematical Formula 7 ] & \\ h 1 + h 2 > {[ \frac{2}{3} E {1}^{′} \frac{{t}_{w 1}^{3}}{γ} ]}^{- \frac{1}{4}} R {1}^{2} & ( 1 ) \\ h 1 + h 2 > {[ \frac{2}{3} E {2}^{′} \frac{{t}_{w 2}^{3}}{γ} ]}^{- \frac{1}{4}} R {2}^{2} & ( 2 )\end{matrix}$$

(7)

The manufacturing method for a semiconductor device according to (5), wherein

the first substrate includes a first semiconductor layer, the first wiring layer is provided above the first semiconductor layer, the second substrate includes a second semiconductor layer, the second wiring layer is provided above the second semiconductor layer, and

the first substrate and the second substrate are formed so that a projection quantity h1 of the first connection electrode from the first interlayer insulation film and a projection quantity h2 of the second connection electrode from the second interlayer insulation film satisfy conditions of the following formulas (3) and (4) in a case where it is assumed that E1/(1−ν1²) be E1′ when it is assumed that E1 be Young's modulus of the first semiconductor layer and ν1 be Poisson's ratio of the first semiconductor layer, E2/(1−ν2²) be E2′ when it is assumed that E2 be the Young's modulus of the second semiconductor layer and ν2 be the Poisson's ratio of the second semiconductor layer, a joint strength between the first interlayer insulation film and the second interlayer insulation film be γ, a thickness of the first semiconductor layer be t_{w1}, and a thickness of the second semiconductor layer be t_{w2}.

$$\begin{matrix}[ Mathematical Formula 8 ] & \\ h 1 + h 2 = {5 [ \frac{γ {t}_{w 1}^{2}}{E {1}^{′}} ]}^{\frac{1}{2}} & ( 3 ) \\ h 1 + h 2 = {5 [ \frac{γ {t}_{w 2}^{2}}{E {2}^{′}} ]}^{\frac{1}{2}} & ( 4 )\end{matrix}$$

(8)

The manufacturing method for a semiconductor device according to (5), wherein

the first substrate includes a first semiconductor layer, the first wiring layer is provided above the first semiconductor layer, the second substrate includes a second semiconductor layer, the second wiring layer is provided above the second semiconductor layer, and

the first substrate and the second substrate are formed so that a projection quantity h1 of the first connection electrode from the first interlayer insulation film and a projection quantity h2 of the second connection electrode from the second interlayer insulation film satisfy conditions of the following formulas (5) and (6) in a case where it is assumed that E1/(1−ν1²) be E1′ when it is assumed that E1 be Young's modulus of the first semiconductor layer and ν1 be Poisson's ratio of the first semiconductor layer, E2/(1−ν2²) be E2′ when it is assumed that E2 be the Young's modulus of the second semiconductor layer and ν2 be the Poisson's ratio of the second semiconductor layer, a joint strength between the first interlayer insulation film and the second interlayer insulation film be γ, a distance between the first connection electrodes adjacent to each other be R1, and a distance between the second connection electrodes adjacent to each other be R2.

(9)

An electronic device including:

a solid imaging apparatus configured to include a sensor substrate including a sensor-side semiconductor layer including a pixel region having a photoelectric converter provided therein and a sensor-side wiring layer having a wiring provided on a side of a surface opposite to a light-receiving surface of the sensor-side semiconductor layer and provided via a sensor-side interlayer insulation film and a sensor-side connection electrode projecting by a predetermined quantity from a surface of the sensor-side interlayer insulation film and a circuit substrate, which is bonded and provided on the sensor substrate, including a circuit-side semiconductor layer and a circuit-side wiring layer having a wiring provided on a side of the sensor-side wiring layer of the sensor substrate and provided via a circuit-side interlayer insulation film and a circuit-side connection electrode projecting by a predetermined quantity from a surface of the circuit-side interlayer insulation film; and

a signal processing circuit configured to perform processing on an output signal output from the solid imaging apparatus, wherein

the solid imaging apparatus includes the sensor-side connection electrode and the circuit-side connection electrode joined with each other and at least a part of a sensor-side interlayer insulation film and a part of a circuit-side interlayer insulation film, which face to each other in a lamination direction, are joined with each other on a bonded surface between the sensor substrate and the circuit substrate.

### REFERENCE SIGNS LIST

1 solid imaging apparatus
2 sensor substrate
3 circuit substrate
4 circuit-side semiconductor layer
5 circuit-side wiring layer
6 circuit-side interlayer insulation film
7, 15, 26, 32, 39 wiring
9 circuit-side connection electrode
10 color filter
11 on-chip lens
12 sensor-side semiconductor layer
13 sensor-side wiring layer
14 sensor-side interlayer insulation film
16 sensor-side connection electrode
17 photoelectric converter
20 semiconductor device
21 first substrate
22 second substrate
23 third substrate
24 first semiconductor layer
25 first wiring layer
27 first interlayer insulation film
28 first connection electrode
30 second semiconductor layer
31 second interlayer insulation film
33 second wiring layer
35 lower-side connection electrode
36 upper-side connection electrode
37 third semiconductor layer
38 third wiring layer
40 third interlayer insulation film
42 third connection electrode
200 electronic device
210 optical lens
211 shutter device
212 drive circuit
213 signal processing circuit

What is claimed is:

1. A semiconductor device comprising:
a first substrate configured to include a first interlayer insulation film and a first wiring layer having a first connection electrode projecting by a predetermined quantity from the first interlayer insulation film; and
a second substrate configured to include a second interlayer insulation film and a second wiring layer having a second connection electrode projecting by a predetermined quantity from the second interlayer insulation film, wherein
the second connection electrode is bonded on the first substrate so as to join with the first connection electrode, and the second connection electrode is joined with the first connection electrode and at the same time at least a part of the first interlayer insulation film and a part of the second interlayer insulation film are joined with each other on the bonded surface.

2. The semiconductor device according to claim 1, wherein
the first substrate includes a first semiconductor layer, the first wiring layer is provided above the first semiconductor layer, the second substrate includes a second semiconductor layer, the second wiring layer is provided above the second semiconductor layer, and
a projection quantity h1 of the first connection electrode from the first interlayer insulation film and a projection quantity h2 of the second connection electrode from the second interlayer insulation film satisfy conditions of the following formulas (1) and (2) in a case where it is assumed that E1/(1−ν1²) be E1′ when it is assumed that E1 be Young's modulus of the first semiconductor layer and ν1 be Poisson's ratio of the first semiconductor layer, E2/(1−ν2²) be E2′ when it is assumed that E2 be the Young's modulus of the second semiconductor layer and ν2 be the Poisson's ratio of the second semiconductor layer, a joint strength between the first interlayer insulation film and the second interlayer insulation film be γ, a distance between the first connection electrodes adjacent to each other be R1, a thickness of the first semiconductor layer be t_{w1}, a distance between the second connection electrodes adjacent to each other be R2, and a thickness of the second semiconductor layer be t_{w2}.
$$\begin{matrix}[ Mathematical Formula 1 ] & \\ h 1 + h 2 > {[ \frac{2}{3} E {1}^{′} \frac{{t}_{w 1}^{3}}{γ} ]}^{- \frac{1}{4}} R {1}^{2} & ( 1 ) \\ h 1 + h 2 > {[ \frac{2}{3} E {2}^{′} \frac{{t}_{w 2}^{3}}{γ} ]}^{- \frac{1}{4}} R {2}^{2} & ( 2 )\end{matrix}$$

3. The semiconductor device according to claim 1, wherein
the first substrate includes a first semiconductor layer, the first wiring layer is provided above the first semiconductor layer, the second substrate includes a second semiconductor layer, the second wiring layer is provided above the second semiconductor layer, and
a projection quantity h1 of the first connection electrode from the first interlayer insulation film and a projection quantity h2 of the second connection electrode from the second interlayer insulation film satisfy conditions of the following formulas (3) and (4) in a case where it is assumed that E1/(1−ν1²) be E1′ when it is assumed that E1 be Young's modulus of the first semiconductor layer and ν1 be Poisson's ratio of the first semiconductor layer, E2/(1−ν2²) be E2′ when it is assumed that E2 be the Young's modulus of the second semiconductor layer and ν2 be the Poisson's ratio of the second semiconductor layer, a joint strength between the first interlayer insulation film and the second interlayer insulation film be γ, a thickness of the first semiconductor layer be t_{w1}, and a thickness of the second semiconductor layer be t_{w1}.
$$\begin{matrix}[ Mathematical Formula 2 ] & \\ h 1 + h 2 = {5 [ \frac{γ {t}_{w 1}^{2}}{E {1}^{′}} ]}^{\frac{1}{2}} & ( 3 ) \\ h 1 + h 2 = {5 [ \frac{γ {t}_{w 2}^{2}}{E {2}^{′}} ]}^{\frac{1}{2}} & ( 4 )\end{matrix}$$

4. The semiconductor device according to claim 1, wherein
the first substrate includes a first semiconductor layer, the first wiring layer is provided above the first semiconductor layer, the second substrate includes a second semiconductor layer, the second wiring layer is provided above the second semiconductor layer, and
a projection quantity h1 of the first connection electrode from the first interlayer insulation film and a projection quantity h2 of the second connection electrode from the second interlayer insulation film satisfy conditions of the following formulas (5) and (6) in a case where it is assumed that E1/(1−ν1²) be E1′ when it is assumed that E1 be Young's modulus of the first semiconductor layer and ν1 be Poisson's ratio of the first semiconductor layer, E2/(1−ν2²) be E2′ when it is assumed that E2 be the Young's modulus of the second semiconductor layer and ν2 be the Poisson's ratio of the second semiconductor layer, a joint strength between the first interlayer insulation film and the second interlayer insulation film be γ, a distance between the first connection electrodes adjacent to each other be R1, and a distance between the second connection electrodes adjacent to each other be R2.
$$\begin{matrix}[ Mathematical Formula 3 ] & \\ h 1 + h 2 > {[ \frac{E {1}^{′}}{12 γ R 1} ]}^{- \frac{1}{2}} & ( 5 ) \\ h 1 + h 2 > {[ \frac{E {2}^{′}}{12 γ R 2} ]}^{- \frac{1}{2}} & ( 6 )\end{matrix}$$

5. A manufacturing method for a semiconductor device, comprising:
a step of preparing a first substrate including a first wiring layer having a first connection electrode projecting by a predetermined quantity from a first interlayer insulation film;
a step of preparing a second substrate including a second wiring layer having a second connection electrode projecting by a predetermined quantity from a second interlayer insulation film; and
a step of bonding the first connection electrode of the first substrate with the second connection electrode of the second substrate while facing them to each other and bonding the first substrate with the second substrate so that the first connection electrode and the second connection electrode are joined and at the same time at least a part of the first interlayer insulation film and a part of the second interlayer insulation film, which face to each other in a lamination direction, are joined with each other on the bonded surface.

6. The manufacturing method for a semiconductor device according to claim 5, wherein
the first substrate includes a first semiconductor layer, the first wiring layer is provided above the first semiconductor layer, the second substrate includes a second semiconductor layer, the second wiring layer is provided above the second semiconductor layer, and
the first substrate and the second substrate are formed so that a projection quantity h1 of the first connection electrode from the first interlayer insulation film and a projection quantity h2 of the second connection electrode from the second interlayer insulation film satisfy conditions of the following formulas (1) and (2) in a case where it is assumed that E1/(1−ν1²) be E1′ when it is assumed that E1 be Young's modulus of the first semiconductor layer and ν1 be Poisson's ratio of the first semiconductor layer, E2/(1−ν2²) be E2′ when it is assumed that E2 be the Young's modulus of the second semiconductor layer and ν2 be the Poisson's ratio of the second semiconductor layer, a joint strength between the first interlayer insulation film and the second interlayer insulation film be γ, a distance between the first connection electrodes adjacent to each other be R1, a thickness of the first semiconductor layer be t_{w1}, a distance between the second connection electrodes adjacent to each other be R2, and a thickness of the second semiconductor layer be t_{w2}.
$$\begin{matrix}[ Mathematical Formula 1 ] & \\ h 1 + h 2 > {[ \frac{2}{3} E {1}^{′} \frac{{t}_{w 1}^{3}}{γ} ]}^{- \frac{1}{4}} R {1}^{2} & ( 1 ) \\ h 1 + h 2 > {[ \frac{2}{3} E {2}^{′} \frac{{t}_{w 2}^{3}}{γ} ]}^{- \frac{1}{4}} R {2}^{2} & ( 2 )\end{matrix}$$

7. The manufacturing method for a semiconductor device according to claim 5, wherein
the first substrate includes a first semiconductor layer, the first wiring layer is provided above the first semiconductor layer, the second substrate includes a second semiconductor layer, the second wiring layer is provided above the second semiconductor layer, and
the first substrate and the second substrate are formed so that a projection quantity h1 of the first connection electrode from the first interlayer insulation film and a projection quantity h2 of the second connection electrode from the second interlayer insulation film satisfy conditions of the following formulas (3) and (4) in a case where it is assumed that E1/(1−ν1²) be E1′ when it is assumed that E1 be Young's modulus of the first semiconductor layer and ν1 be Poisson's ratio of the first semiconductor layer, E2/(1−ν2²) be E2′ when it is assumed that E2 be the Young's modulus of the second semiconductor layer and ν2 be the Poisson's ratio of the second semiconductor layer, a joint strength between the first interlayer insulation film and the second interlayer insulation film be γ, a thickness of the first semiconductor layer be t_{w1}, and a thickness of the second semiconductor layer be t_{w2}.
$$\begin{matrix}[ Mathematical Formula 2 ] & \\ h 1 + h 2 = {5 [ \frac{γ {t}_{w 1}^{2}}{E {1}^{′}} ]}^{\frac{1}{2}} & ( 3 ) \\ h 1 + h 2 = {5 [ \frac{γ {t}_{w 2}^{2}}{E {2}^{′}} ]}^{\frac{1}{2}} & ( 4 )\end{matrix}$$

8. The manufacturing method for a semiconductor device according to claim 5, wherein
the first substrate includes a first semiconductor layer, the first wiring layer is provided above the first semiconductor layer, the second substrate includes a second semiconductor layer, the second wiring layer is provided above the second semiconductor layer, and
the first substrate and the second substrate are formed so that a projection quantity h1 of the first connection electrode from the first interlayer insulation film and a projection quantity h2 of the second connection electrode from the second interlayer insulation film satisfy conditions of the following formulas (5) and (6) in a case where it is assumed that E1/(1−ν1²) be E1′ when it is assumed that E1 be Young's modulus of the first semiconductor layer and ν1 be Poisson's ratio of the first semiconductor layer, E2/(1−ν2²) be E2′ when it is assumed that E2 be the Young's modulus of the second semiconductor layer and ν2 be the Poisson's ratio of the second semiconductor layer, a joint strength between the first interlayer insulation film and the second interlayer insulation film be γ, a distance between the first connection electrodes adjacent to each other be R1, and a distance between the second connection electrodes adjacent to each other be R2.
$$\begin{matrix}[ Mathematical Formula 3 ] & \\ h 1 + h 2 > {[ \frac{E {1}^{′}}{12 γ R 1} ]}^{- \frac{1}{2}} & ( 5 ) \\ h 1 + h 2 > {[ \frac{E {2}^{′}}{12 γ R 2} ]}^{- \frac{1}{2}} & ( 6 )\end{matrix}$$

9. An electronic device comprising:
a solid imaging apparatus configured to include a sensor substrate including a sensor-side semiconductor layer including a pixel region having a photoelectric converter provided therein and a sensor-side wiring layer having a wiring provided on a side of a surface opposite to a light-receiving surface of the sensor-side semiconductor layer and provided via a sensor-side interlayer insulation film and a sensor-side connection electrode projecting by a predetermined quantity from a surface of the sensor-side interlayer insulation film and a circuit substrate, which is bonded and provided on the sensor substrate, including a circuit-side semiconductor layer and a circuit-side wiring layer having a wiring provided on a side of the sensor-side wiring layer of the sensor substrate and provided via a circuit-side interlayer insulation film and a circuit-side connection electrode projecting by a predetermined quantity from a surface of the circuit-side interlayer insulation film; and
a signal processing circuit configured to perform processing on an output signal output from the solid imaging apparatus, wherein
the solid imaging apparatus includes the sensor-side connection electrode and the circuit-side connection electrode joined with each other and at least a part of a sensor-side interlayer insulation film and a part of a circuit-side interlayer insulation film, which face to each other in a lamination direction, are joined with each other on a bonded surface between the sensor substrate and the circuit substrate.
